(19) United States
(12) Patent Application Publication
(10) Pub. No.: US 2025/0349810 A1
(43) Pub. Date: Nov. 13, 2025

(54) SEMICONDUCTOR PACKAGE AND METHOD

(71) Applicant: Taiwan Semiconductor Manufacturing Co., Ltd., Hsinchu (TW)

(72) Inventors: Chen-Hua Yu, Hsinchu (TW); Hsing-Kuo Hsia, Jhubei City (TW)

(21) Appl. No.: 19/275,070

(22) Filed: Jul. 21, 2025

Related U.S. Application Data
(63) Continuation of application No. 18/628,173, filed on Apr. 5, 2024.
(60) Provisional application No. 63/601,276, filed on Nov. 21, 2023.
(60) Provisional application No. 63/601,801, filed on Nov. 22, 2023.

(51) Int. Cl. H01L 25/16; H01L 21/56; H01L 23/00; H01L 23/31

(52) U.S. Cl. CPC H01L 25/167; H01L 21/568; H01L 23/3107; H01L 24/08; H01L 24/16; H01L 2224/08237; H01L 2224/16225; H01L 2924/1433

(57) ABSTRACT

A semiconductor package includes a redistribution structure, first and second integrated circuit dies that are connected to a first side of the redistribution structure, and third and fourth integrated circuit dies that are connected on a second side, opposite to the first side, of the redistribution structure. An optical bridge die is connected between the third and fourth integrated circuit dies, to the second side of the redistribution structure, which is configured such that the first and second integrated circuit dies optically communicate through the optical bridge die.

### PRIORITY CLAIM AND CROSS-REFERENCE

This application is a continuation of U.S. application Ser. No. 18/628,173, filed on Apr. 5, 2024, which claims the benefit of U.S. Provisional Application No. 63/601,276, filed on Nov. 21, 2023, entitled “STRUCTURE TO INTEGRATE PHOTONIC SILICON WITH CHIPLET IN A 3DIC PACKAGE,” and U.S. Provisional Application No. 63/601,801, filed on Nov. 22, 2023, entitled “PACKAGE STRUCTURE,” which are incorporated herein by reference.

### BACKGROUND

The semiconductor industry continues to improve the integration density of various electronic components (e.g., transistors, diodes, resistors, capacitors, etc.) by continual reductions in minimum feature size, which allow more components, hence more functions, to be integrated into a given area. Integrated circuits with high functionality require many input/output pads. Yet, small packages may be desired for applications where miniaturization is important. Integrated package technology is becoming increasingly popular, particularly when combined with Wafer Level Packaging (WLP) technology in which integrated circuits are packaged in packages that typically include a redistribution layer (RDL), a redistribution structure, or an interposer. It is highly desirable that high speed reliable communication is provided between integrated circuits of the package.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B illustrates cross-sectional views of an integrated circuit die, in accordance with some embodiments.

FIGS. 2, 3, 4, 5, 6, 7, and 8 illustrate cross-sectional views of intermediate stages for producing a semiconductor package that includes semiconductor devices, in accordance with some embodiments.

FIGS. 9A, 9B, 10A, and 10B illustrate cross-sectional views of a semiconductor package that includes semiconductor devices and optical bridges, in accordance with some embodiments.

FIGS. 11A, 11B, 11C, 11D, 11E, 11F, and 11G illustrate cross-sectional views of intermediate stages for producing an optical bridge.

FIGS. 12A, 12B, 12C, 12D, and 12E illustrate a cross-sectional view of a semiconductor package on a substrate, a solder bump structure, a system-level diagram of an optical interface engine, and a cross-sectional view of and optical interface engine, in accordance with some embodiments.

FIGS. 13, 14, 15, and 16 illustrate a cross-sectional view of a semiconductor package, an optical interface engine, and a device mounted on an interposer and the interposer is mounted on a substrate, in accordance with some embodiments.

FIGS. 17A, 17B, and 17C illustrate a plan view of the semiconductor package.

FIG. 18 illustrates a flow diagram of a process for generating a packaged semiconductor device, according to some embodiments of the disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, in a semiconductor package, a plurality of integrated circuit dies, e.g., systems on a chip (SoCs) or semiconductor devices, may be attached to an interposer or a redistribution structure. The plurality of integrated circuit dies may communicate with each other via the redistribution structure or the interposer. In addition to the interposer or the redistribution structure, the plurality of integrated circuit dies may communicate through one or more local silicon interconnect (LSI) devices. Utilizing fiber optical communication between two or more integrated circuit dies may increase the communication speed and may reduce communication noise. Thus, for a first portion of the integrated circuit dies, an optical bridge may be placed or mounted next to the integrated circuit dies or between each two integrated circuit dies, e.g., on the interposer or on the redistribution structure. The optical bridge may be used by the first portion of the integrated circuit dies to communicate, e.g., provide optical communication between the first portion of the integrated circuit dies. An integrated circuit die my convert the electrical signals to optical signals and may send the optical signals to the optical bridge. The other integrated circuit die or dies may receive the optical signal from the optical bridge and may convert the optical signals to electrical signals to re-generate the electrical signals. The integrated circuit dies may communicate with a remaining second portion of the integrated circuit dies, e.g., memory dies, via the interposer or the redistribution structure and using the electrical signals.

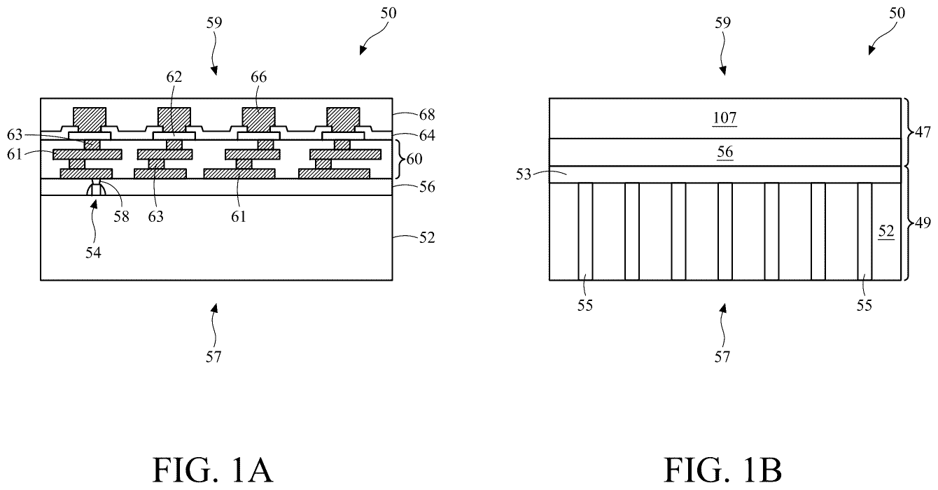

FIGS. 1A and 1B illustrates cross-sectional views of an integrated circuit die 50, in accordance with some embodiments. FIG. 1A illustrates the cross-sectional view of the integrated circuit die 50, e.g., a semiconductor die or a device die. The integrated circuit die 50 will be packaged as described in the following to form a semiconductor package. The integrated circuit die 50 may be, e.g., may include, a logic die (e.g., a central processing unit (CPU), a graphics processing unit (GPU), a system-on-a-chip (SoC), and application processor (AP), a microcontroller, etc.). The integrated circuit die 50 may be a memory die (e.g., a dynamic random access memory (DRAM) die, a static random access memory (SRAM) die, etc.). The integrated circuit die 50 may be one of a power management die (e.g., a power management integrated circuit (PMIC) die), a radio frequency (RF) die, a sensor die, a micro-electro-mechanical-system (MEMS) die, a signal processing die (e.g., digital signal processing (DSP) die), a front-end die (e.g., an analog front-end (AFE) die), and the like, or a combinations thereof.

The integrated circuit die 50 may be formed in a wafer, which may include different device regions that are singulated in subsequent steps to form a plurality of integrated circuit dies. The integrated circuit die 50 may be processed according to applicable manufacturing processes to form integrated circuits. In some embodiments, the integrated circuit die 50 includes a semiconductor substrate 52, such as a silicon substrate, doped or undoped. The semiconductor substrate 52 may include an active layer of a semiconductor-on-insulator (SOI) substrate. The semiconductor substrate 52 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. In some embodiments, the semiconductor substrate 52 has an active surface (e.g., the surface facing upwards in FIG. 1), which may be called a front side, and has an inactive surface (e.g., the surface facing downwards in FIG. 1), which may be called a back side.

One or more devices 54, e.g., one device shown in FIG. 1, may be formed at the front surface of the semiconductor substrate 52. The devices 54 may be active devices (e.g., transistors, diodes, etc.), or passive devices (e.g. capacitors, resistors, etc.) An inter-layer dielectric (ILD) 56 is formed over the front surface of the semiconductor substrate 52. The ILD 56 may surround and may cover the devices 54. Thus, the ILD 56 that includes the devices 54 is also a semiconductor device layer. The ILD 56 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like.

Conductive plugs 58 may extend through the ILD 56 to electrically and physically couple the devices 54. In some embodiments, when the devices 54 are transistors, the conductive plugs 58 may couple to the gates and/or to the source/drain regions of the transistors. Source/drain region(s) may refer to a source or a drain region, individually or collectively dependent upon the context. The conductive plugs 58 may be formed of tungsten, cobalt, nickel, copper, silver, gold, aluminum, the like, or combinations thereof. In some embodiments, an interconnect layer 60 is formed over the ILD 56 and conductive plugs 58. The interconnect layer 60 may include an interconnect structure coupled to the conductive plugs 58 of the devices 54 to interconnect the devices 54 to form an integrated circuit. The interconnect structure of the interconnect layer 60 may be formed by, for example, metallization patterns in dielectric layers on the ILD 56. The metallization patterns include metal lines and vias formed in one or more low-k dielectric layers. As described, the metallization patterns of the interconnect layer 60 are electrically coupled to the devices 54 via the conductive plugs 58. The interconnect structure in the interconnect layer 60 may include conductive layers 61 that are connected to each other through vias 63. In some embodiments, the interconnect structure of the interconnect layer 60 is a redistribution structure.

The integrated circuit die 50 further includes pads 62, such as aluminum pads, to which external connections are made. The pads 62 are on the active side of the integrated circuit die 50, such as in and/or on the interconnect layer 60 and in contact with the interconnect structure. One or more passivation films 64 are on the integrated circuit die 50, such as on portions of the interconnect layer 60 and pads 62. Openings extend through the passivation films 64 to the pads 62. Die connectors 66, such as conductive pillars (for example, formed of a metal such as copper), extend through the openings in the passivation films 64 and are physically and electrically coupled to respective ones of the pads 62. The die connectors 66 may be formed by, for example, plating, or the like. The die connectors 66 electrically couple the respective integrated circuits of the integrated circuit die 50.

Optionally, solder regions (e.g., solder balls or solder bumps) may be disposed on the pads 62. The solder balls may be used to perform chip probe (CP) testing on the integrated circuit die 50. CP testing may be performed on the integrated circuit die 50 to ascertain whether the integrated circuit die 50 is a known good die (KGD). Thus, only integrated circuit dies 50, which are KGDs, undergo subsequent processing and are packaged, and dies, which fail the CP testing, are not packaged. After testing, the solder regions may be removed in subsequent processing steps.

A dielectric layer 68 may (or may not) be formed on the active side of the integrated circuit die 50, such as on the passivation films 64 and the die connectors 66. The dielectric layer 68 laterally encapsulates the die connectors 66, and the dielectric layer 68 is laterally coterminous with the integrated circuit die 50. Initially, the dielectric layer 68 may bury the die connectors 66, such that the topmost surface of the dielectric layer 68 is above the topmost surfaces of the die connectors 66. In some embodiments where solder regions are disposed on the die connectors 66, the dielectric layer 68 may bury the solder regions as well. Alternatively, the solder regions may be removed prior to forming the dielectric layer 68.

The dielectric layer 68 may be a polymer such as PBO, polyimide, BCB, or the like; a nitride such as silicon nitride or the like; an oxide such as silicon oxide, PSG, BSG, BPSG, or the like; the like, or a combination thereof. The dielectric layer 68 may be formed, for example, by spin coating, lamination, chemical vapor deposition (CVD), or the like. In some embodiments, the die connectors 66 are exposed through the dielectric layer 68 during formation of the integrated circuit die 50. In some embodiments, the die connectors 66 remain buried and are exposed during a subsequent process for packaging the integrated circuit die 50. Exposing the die connectors 66 may remove the solder regions that may be present on the die connectors 66.

In some embodiments, the integrated circuit die 50 is a stacked device that includes multiple semiconductor substrates 52. For example, the integrated circuit die 50 may be a memory device such as a hybrid memory cube (HMC) module, a high bandwidth memory (HBM) module, or the like that includes multiple memory dies. In such embodiments, the integrated circuit die 50 includes multiple semiconductor substrates 52 interconnected by through-substrate vias (TSVs). Each of the semiconductor substrates 52 may (or may not) have an interconnect layer 60 or the interconnect structure. As shown, a backside of the semiconductor substrate 52 of the integrated circuit die 50 away from the ILD 56 is a backside 57 of the integrated circuit die 50 and a side of the integrated circuit die 50, opposite of the backside 57 is a front side 59 of the integrated circuit die 50.

FIG. 1B illustrates the cross-sectional view of the integrated circuit die 50 and is consistent with the integrated circuit die 50 of FIG. 1A. In FIG. 1B, a front-side interconnect structure 107 may be a combination of the dielectric layer 68 that includes the die connectors 66, the passivation films 64 that include the pads 62, and the interconnect layer 60. As shown, in some embodiments, a combination of the front-side interconnect structure 107 and the ILD 56 is presented as a layer 47.

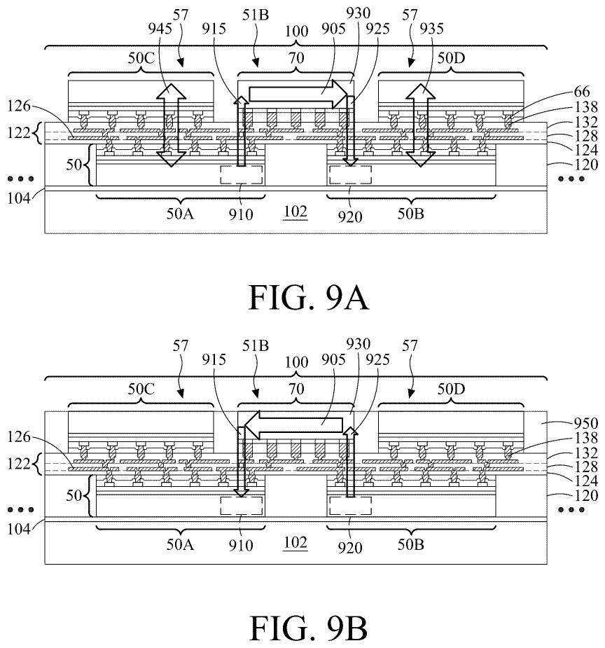

In some embodiments, as shown in FIG. 5 below, the dielectric layer 68 is etched such that the die connectors 66 are exposed. In addition, FIG. 1B includes a backside metallization layer 53 that is formed between the semiconductor substrate 52 and the ILD 56. As shown, the semiconductor substrate 52 includes TSVs 55 that are exposed at the backside 57. In some embodiments, a combination of the backside metallization layer 53 and the semiconductor substrate 52 that includes the TSVs 55 is a backside interconnect structure 49. In some embodiments, the TSVs 55 are formed in the semiconductor substrate 52, e.g., a silicon substrate, prior to forming the backside metallization layer 53 by patterning via locations associated with the TSVs 55, etching the trenches through the silicon substrate, and filling the trenches with insulating liners and conductive material. Then, after forming the integrated circuit die 50, the backside 57 is polished, e.g., chemical mechanical polishing (CMP), to expose the TSVs 55.

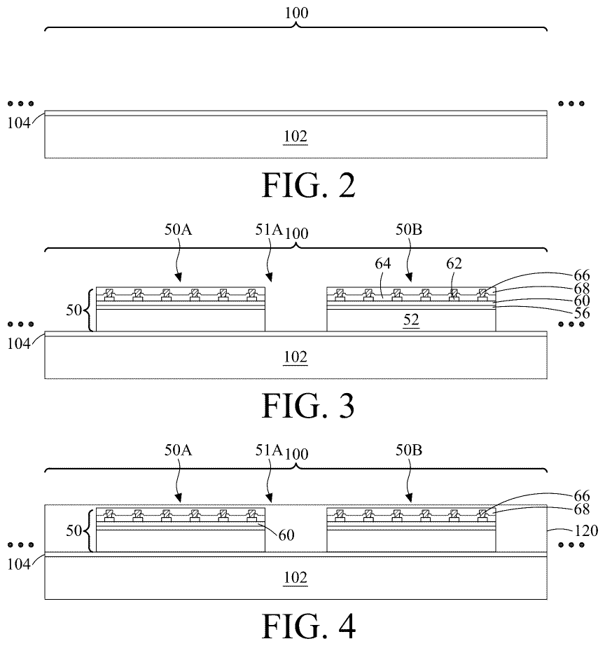

FIGS. 2, 3, 4, 5, 6, 7, and 8 illustrate cross-sectional views of intermediate stages for producing a semiconductor package that includes semiconductor devices, in accordance with some embodiments. In FIG. 2, a carrier substrate 102 is provided, and a release layer 104 is formed on the carrier substrate 102. The carrier substrate 102 may be a glass carrier substrate, a ceramic carrier substrate, or the like. The carrier substrate 102 may be a wafer, such that multiple packages can be formed on the carrier substrate 102 simultaneously.

The release layer 104 may be formed of a polymer-based material, which may be removed along with the carrier substrate 102 from the overlying structures that will be formed in subsequent steps. In some embodiments, the release layer 104 is an epoxy-based thermal-release material, which loses its adhesive property when heated, such as a light-to-heat-conversion (LTHC) release coating. In other embodiments, the release layer 104 may be an ultra-violet (UV) glue, which loses its adhesive property when exposed to UV lights. The release layer 104 may be dispensed as a liquid and cured, may be a laminate film laminated onto the carrier substrate 102, or may be the like. The top surface of the release layer 104 may be leveled and may have a high degree of planarity.

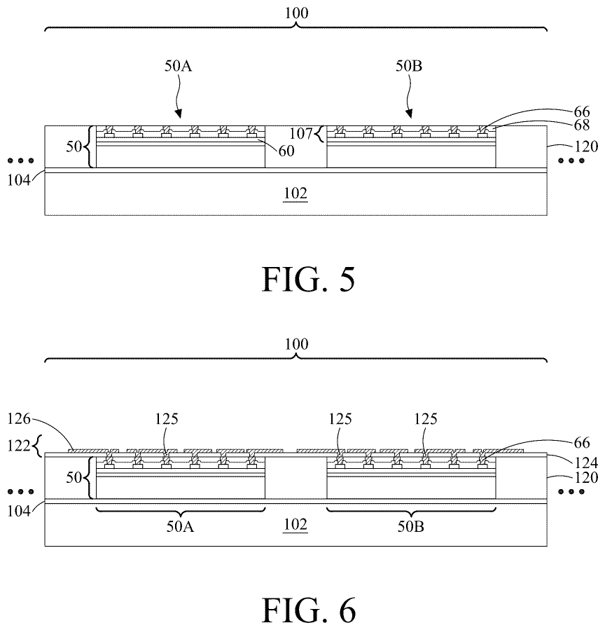

In FIG. 3, integrated circuit dies 50 (e.g., a first integrated circuit die 50A and a second integrated circuit die 50B) are connected to the release layer 104. A desired type and quantity of integrated circuit dies 50 are adhered in each of the package regions 100. In the embodiment shown, multiple integrated circuit dies 50 are adhered adjacent one another, including the first integrated circuit die 50A and the second integrated circuit die 50B in each of the package region 100. The first integrated circuit die 50A and the second integrated circuit die 50B may be an application-specific integrated circuit (ASIC). Also, the first integrated circuit die 50A and the second integrated circuit die 50B may be a log integrated circuit device, such as a CPU, a GPU, a SoC, an AP, a microcontroller, or the like. Or, may be a memory device, such as a DRAM die, an SRAM die, a hybrid memory cube (HMC) module, a high bandwidth memory (HBM) module, or the like. In some embodiments, the integrated circuit dies 50A and 50B may be the same type of dies, such as SoC dies. The first integrated circuit die 50A and second integrated circuit die 50B may be formed in processes of a same technology node, or may be formed in processes of different technology nodes. For example, the first integrated circuit die 50A may be of a more advanced process node than the second integrated circuit die 50B. The integrated circuit dies 50A and 50B may have different sizes (e.g., different heights and/or surface areas), or may have the same size (e.g., same heights and/or surface areas).

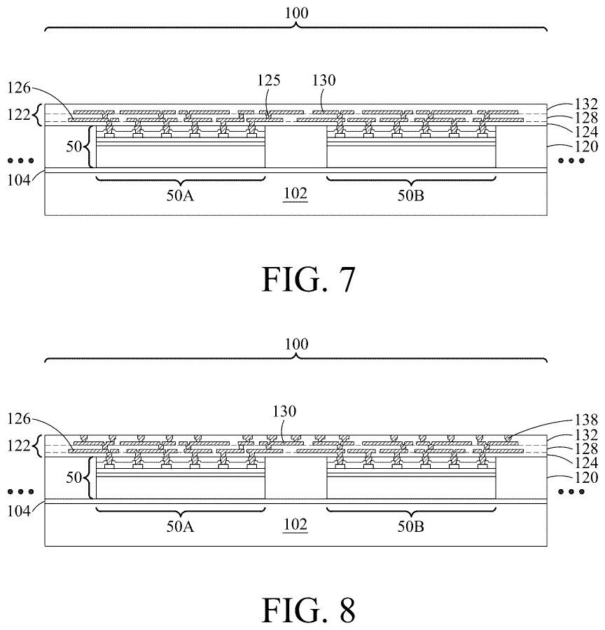

In FIG. 4, an encapsulant 120, e.g., an encapsulant material, is formed on and around the integrated circuit dies 50. After formation, the encapsulant 120 encapsulates the integrated circuit dies 50. The encapsulant 120 may be a molding compound, epoxy, or the like. The encapsulant 120 may be applied by compression molding, transfer molding, or the like, and may be formed over the carrier substrate 102 such that the integrated circuit dies 50 are buried or covered. The encapsulant 120 is further formed in gap regions 51A between the integrated circuit dies 50. The encapsulant 120 may be applied in liquid or semi-liquid form and then subsequently cured. In some embodiments, the integrated circuit dies 50 in each package region 100 are next to each other, e.g., at proximity of each other, such that an extent of the gap region 51A between integrated circuit dies 50 in the package regions 100 is about the same extent as that the extent of the integrated circuit dies 50. In some embodiments, the extent of the gap region 51A is in a range between 50 percent greater and 50 percent smaller than a maximum extent of the integrated circuit dies 50. In some embodiments, the encapsulant 120 extends from the backside 57 to the front side 59 of the integrated circuit dies 50 and surround a height of the integrated circuit dies 50 and may cover the front side 59 of the integrated circuit dies 50.

In FIG. 5, a planarization process is performed on the encapsulant 120 to expose the die connectors 66, e.g., connection pads of the integrated circuit dies 50. The planarization process may also remove material of the dielectric layer 68 and/or the die connectors 66 until the die connectors 66 are exposed, e.g., a top surface of the die connectors 66 are exposed. Top surfaces of the die connectors 66, the dielectric layer 68, and the encapsulant 120 are substantially coplanar after the planarization process within process variations. The planarization process may be, for example, a chemical-mechanical polish (CMP), a grinding process, or the like. In some embodiments, the planarization may be omitted, for example, if the die connectors 66 are already exposed. FIG. 5 also shows the front-side interconnect structure 107 with the die connectors 66 that are exposed.

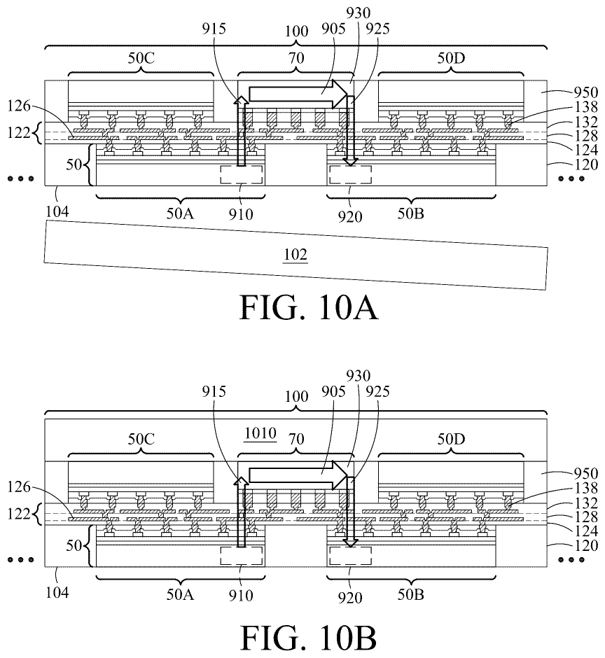

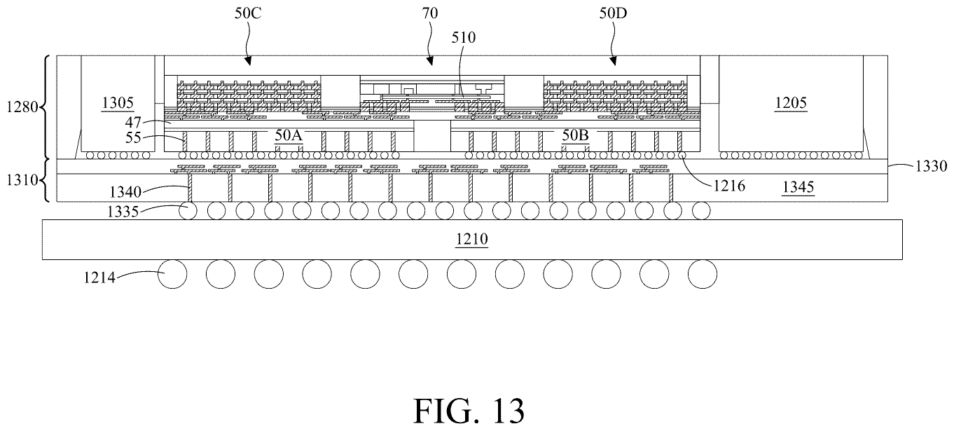

In FIGS. 6 through 8, a redistribution structure 122, e.g., a front-side redistribution structure (see FIG. 13) is formed over the encapsulant 120 and integrated circuit dies 50. The redistribution structure 122 includes dielectric layers 124, 128, and 132; and metallization patterns 126 and 130. The metallization patterns may also be referred to as redistribution layers or redistribution lines. The redistribution structure 122 is shown as an example having three layers of metallization patterns. More or fewer dielectric layers and metallization patterns may be formed in the redistribution structure 122. If fewer dielectric layers and metallization patterns are to be formed, steps and process discussed below may be omitted. If more dielectric layers and metallization patterns are to be formed, steps and processes discussed below may be repeated.

In FIG. 6, the dielectric layer 124 is deposited on the encapsulant 120 and die connectors 66. In some embodiments, the dielectric layer 124 is formed of a photo-sensitive material such as PBO, polyimide, BCB, or the like, which may be patterned using a lithography mask. The dielectric layer 124 may be formed by spin coating, lamination, CVD, the like, or a combination thereof. The dielectric layer 124 is then patterned. The patterning forms openings exposing portions of the die connectors 66. The patterning may be by an acceptable process, such as by exposing and developing the dielectric layer 124 to light when the dielectric layer 124 is a photo-sensitive material or by etching using, for example, an anisotropic etch.

The metallization pattern 126 is then formed. The metallization pattern 126 includes conductive elements extending along the major surface of the dielectric layer 124 and extending through the dielectric layer 124 to physically and electrically couple to the integrated circuit dies 50, e.g., couple to the die connectors 66. As an example to form the metallization pattern 126, a seed layer is formed over the dielectric layer 124 and in the openings extending through the dielectric layer 124. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization pattern 126. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the metallization pattern 126. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. As shown, the die connectors 66 of the integrated circuit dies 50 (e.g., the integrated circuit dies 50A and 50B of FIG. 6) are bonded through vias 125 of the metallization pattern 126 to the redistribution structure 122.

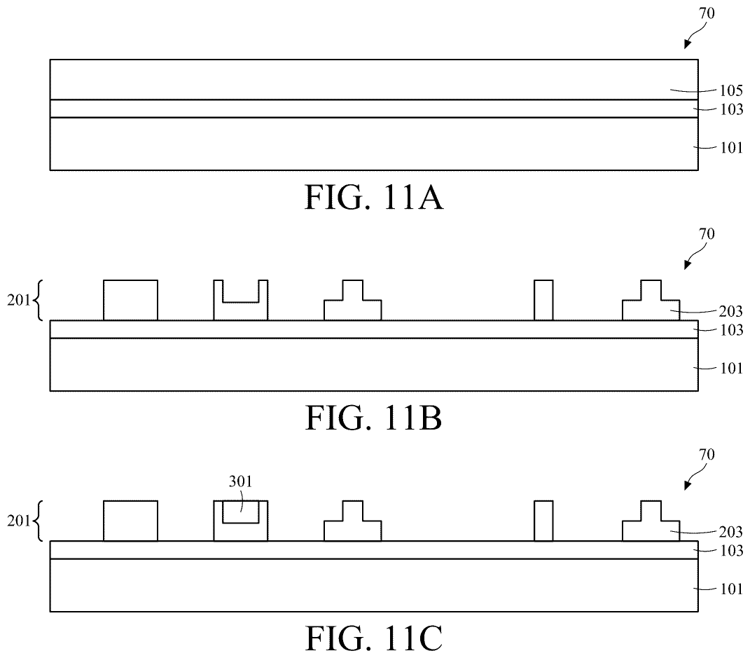

In FIG. 7, the dielectric layer 128 is deposited on the metallization pattern 126 and the dielectric layer 124. The dielectric layer 128 may be formed in a manner similar to the dielectric layer 124, and may be formed of a similar material as the dielectric layer 124.

The metallization pattern 130 is then formed. The metallization pattern 130 includes portions on and extending along the major surface of the dielectric layer 128. The metallization pattern 130 further includes portions extending through the dielectric layer 128 to physically and electrically couple to the metallization pattern 126. The metallization pattern 130 may be formed in a similar manner and of a similar material as the metallization pattern 126. In some embodiments, the metallization pattern 130 has a different size than the metallization pattern 126. For example, the conductive lines and/or vias of the metallization pattern 130 may be wider or thicker than the conductive lines and/or vias of the metallization pattern 126. Further, the metallization pattern 130 may be formed to a greater pitch than the metallization pattern 126. The metallization pattern 130 may be connected to the metallization pattern 126 through vias 125 of the metallization pattern 130.

Additionally, as shown in FIG. 7, the dielectric layer 132 is deposited on the metallization pattern 130 and the dielectric layer 128. The dielectric layer 132 may be formed in a manner similar to the dielectric layer 124, and may be formed of a similar material as the dielectric layer 124. The metallization pattern 130 is the topmost metallization pattern of the redistribution structure 122. As such, all of the intermediate metallization patterns of the redistribution structure 122 (e.g., the metallization pattern 126) are disposed between the metallization pattern 130 and the integrated circuit dies 50. In some embodiments, the redistribution structure 122 may be formed by a similar process and materials as the interconnect layer 60 described above.

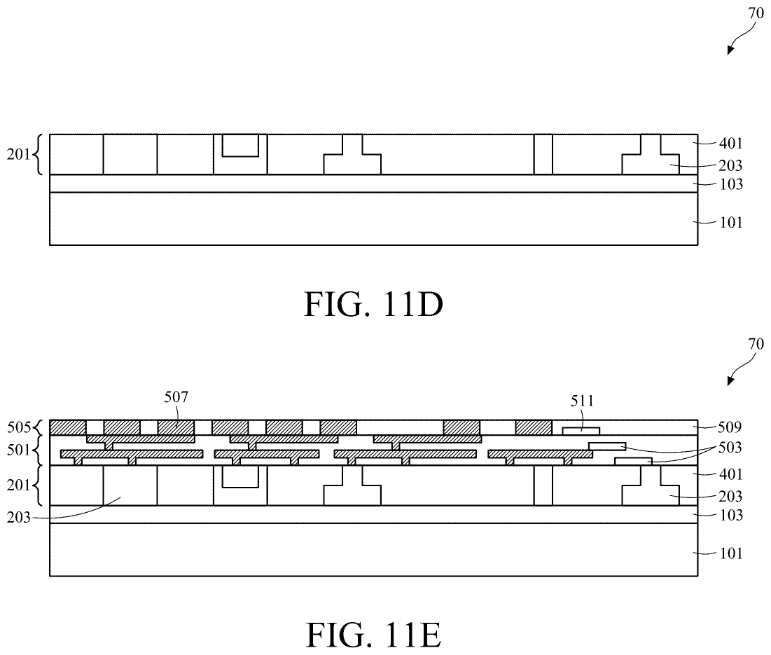

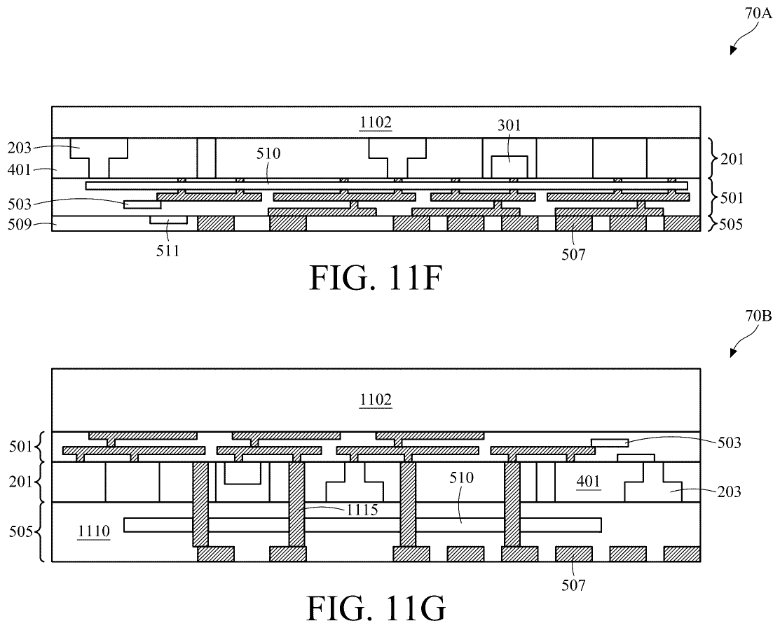

In FIG. 8, bond pads 138, which are conductive features, are formed on and connected to the metallization pattern 130 for external connection to the redistribution structure 122. As a result, the bond pads 138 are electrically coupled to the integrated circuit dies 50 (e.g., the integrated circuit dies 50C and 50D of FIGS. 9A and 9B). The bond pads 138 may be formed of the same material as the metallization pattern 126. In some embodiments, the bond pads 138 have a different size than the metallization patterns 126 and 130.

The bond pads 138 may be conductive pillars, pads, or the like and be formed in the dielectric layer 132. The bond pads 138 can be formed of a metal, such as copper, aluminum, or the like, and can be formed by, for example, by plating, or the like. In some embodiments, the bond pads 138 may be electrically connected to metallization pattern 130 by conductive vias (sometimes referred to as bond pad vias). The dielectric layer 132 may be made of a material suitable for subsequent dielectric-to-dielectric bonding, such as, silicon oxide, silicon oxynitride, or the like. The dielectric layer 132 may be deposited by, for example, spin coating, lamination, chemical vapor deposition (CVD), or the like. A planarization process (e.g., a chemical mechanical polish (CMP) or the like) may be performed such that top surfaces of the bond pads 138 and the dielectric layer 132 are coplanar (within process variations). As will be described in greater detail below, the planarized surfaces of the bond pads 138 and the dielectric layer 132 are bonded to semiconductor dies.

In some embodiments, the dielectric layer 132 has a different material composition than the other dielectric layers in the redistribution structure 122 to provide a better material for the subsequent bonding process. In some embodiments, an insulating bonding layer is formed over the dielectric layer 132 and that insulating bonding layer is used for the subsequent bonding process.

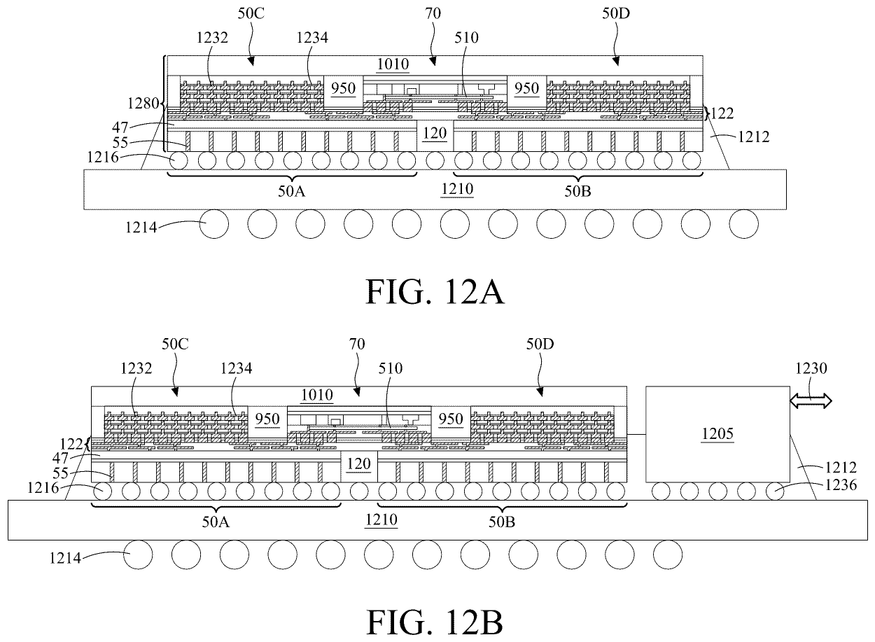

FIGS. 9A, 9B, 10A and 10B illustrate cross-sectional views of a semiconductor package that includes semiconductor devices and optical bridges, in accordance with some embodiments. FIGS. 9A and 9B are similar to FIG. 8 with the difference that additional integrated circuit dies 50C and 50D are bonded to the redistribution structure 122 on an opposite side that the integrated circuit dies 50A and 50B are connected. As shown, the die connectors 66 of the integrated circuit dies 50C and 50D may be connected to the bond pads 138. The die connectors 66 and the dielectric layer 68 of the integrated circuit dies 50C and 50D may be similar to the bond pads 138 and the dielectric layer 132 described above. As shown, there may be another gap region 51B between the integrated circuit dies 50C and 50D. An optical bridge die 70 may be connected in the gap region 51B to the bond pads 138 of the redistribution structure 122 on the same side the integrated circuit dies 50C and 50D are connected. The optical bridge die 70 may have active circuitry and may receive electrical signals such as power and ground connections via the bond pads 138 of the redistribution structure 122 that may be connected to die connectors 66 of optical bridge die 70. In some embodiments, the optical bridge die 70 is mounted on the redistribution structure 122 and has a height that may extend up to the backside 57 of the integrated circuit dies 50C and 50D. Thus, the optical bridge die 70, providing communication between the integrated circuit dies 50C and 50D, is coplanar with the integrated circuit dies 50C and 50D that are also mounted on the redistribution structure 122, which improves lateral integration of the integrated circuit dies. In addition, other integration circuit dies may be mounted over the integrated circuit dies 50C and 50D and the optical bridge die 70.

The integrated circuit dies 50C and 50D and the redistribution structure 122 are directly bonded by a dielectric-to-dielectric bonding and metal-to-metal bonding process (sometimes referred to as direct bonding), such that the front sides of the integrated circuit dies 50C and 50D are the redistribution structure 122. Specifically, the dielectric layers 68 of the integrated circuit dies 50C and 50D are bonded to the dielectric layer 132 of the redistribution structure 122 through dielectric-to-dielectric bonding, without using any adhesive material (e.g., die attach film), and the die connectors 66 of the integrated circuit dies 50C and 50D are bonded to the bond pads 138 of the redistribution structure 122 through metal-to-metal bonding, without using any eutectic material (e.g., solder). The bonding may include a surface activation, a pre-bonding, and an annealing. The surface activation may include activating the dielectric layers 68 and/or 132 may be performed using, e.g., a dry treatment, a wet treatment, a plasma treatment, exposure to H₂, exposure to N₂, exposure to O₂, combinations of these, or the like. In embodiments where a wet treatment is used, an RCA cleaning process may be used, for example. Through the activation treatment, the number of OH groups at surface(s) of the dielectric layers 68 and/or 132 increases. After surfaces of the dielectric layers 68 and/or 132 are activated, a pre-bonding is performed by applying a small pressing force to press the integrated circuit dies 50C and 50D against the redistribution structure 122. The pre-bonding is performed at a low temperature, such as room temperature, such as a temperature in the range of about 15° C. to about 30° C. The bonding strength of the dielectric layers 68 and 132 is then improved in a subsequent annealing step, in which the dielectric layers 68 and 132 are annealed at a high temperature, such as a temperature in the range of about 100° C. to about 450° C. After the annealing, bonds, such as covalent bonds, are formed bonding the dielectric layers 68 and 132. The die connectors 66 and the bond pads 138 may be in physical contact after the pre-bonding, or may expand to be brought into physical contact during the annealing. Further, during the annealing, the material of the die connectors 66 and the bond pads 138 (e.g., copper) intermingles, so that metal-to-metal bonds are also formed. Hence, the resulting bonds are direct bonds that include both dielectric-to-dielectric bonds and metal-to-metal bonds.

In some embodiments, the integrated circuit dies 50C and 50D are bonded to the redistribution structure 122 using solder bumps and reflow processes.

In some embodiments, as shown in FIGS. 9A, the integrated circuit die 50A sends optical signals via an optical transmission channel 915 to a first end of an optical structure 930 of the optical bridge die 70. The optical bridge die 70 sends the optical signals via an optical transmission channel 905 of the optical bridge die 70 to a second end of the optical bridge die 70. The optical bridge die 70 may then send the optical signals to the integrated circuit die 50B via an optical transmission channel 925. In some embodiments, the integrated circuit die 50A includes a signal converter for converting electrical signals to optical signals and converting optical signals to electrical signals, e.g., an electrical/optical signal converter 910. The integrated circuit die 50B may include the signal converter, e.g., an electrical/optical signal converter 920. The electrical/optical signal converter 910 or 920 may include a light source such as emitting diode or a laser diode and may include a light detector. The electrical/optical signal converter 910 (e.g., the signal converter) may generate the optical signals based on the electric signal of the integrated circuit die 50A, e.g., the electrical signals of the integrated circuit die 50A that are required to be transmitted to the integrated circuit die 50B. Also, the electrical/optical signal converter 920 (e.g., the signal converter) may generate, e.g., re-produce or re-generate, the electrical signals by a light detector and based on the optical signals received from the optical bridge die 70. Thus, the integrated circuit dies 50A and 50B may communicate using optical signals and through the optical bridge die 70.

In some embodiments, as shown in FIGS. 9B, the integrated circuit die 50B sends optical signals via the optical transmission channel 925 to the second end of the optical bridge die 70. The optical bridge die 70 sends the optical signals via the optical transmission channel 905 to the first end of the optical bridge die 70. The optical bridge die 70 may then send the optical signals to the integrated circuit die 50A via the optical transmission channel 915. Also, the electrical/optical signal converter 920 includes a light source such as a light emitting diode or a laser diode to generate the optical signals based on the electrical signals, and the electrical/optical signal converter 910 includes a light detector, to generate (e.g., re-produce) the electrical signals based on the optical signals received from the optical bridge die 70. In some embodiments, the optical signals generated by the electrical/optical signal converters 910 and 920 are collimated by one or more optical components, e.g., lenses and/or waveguides, of the electrical/optical signal converters 910 and 920 and pass through the redistribution structure 122 to reach the optical bridge die 70. Thus, the optical transmission channel 915 and/or 925 may be a waveguide such as an optical fiber or a free space transmission channel. The optical bridge die 70 may include an optical component such as a mirror at both ends of the optical bridge die 70 that causes the light to divert to align from the direction of the optical transmission channel 905 to the directions of the optical transmission channel 915 and 925 and vice versa.

As discussed above, the optical transmission channels 905, 915, and 925 may be bi-directional and the electrical/optical signal converters 910 and 920 both include a light detector as well as a light emitting diode such as a laser diode. In some embodiments, an encapsulant 950, e.g., an encapsulant material, is formed on the redistribution structure 122 on the same side the integrated circuit dies 50C and 50D are connected such that the encapsulant 950 surrounds around and over the optical bridge die 70 and the integrated circuit dies 50C and 50D. In some embodiments, a planarization process is performed on the encapsulant 950 to remove the encapsulant material up to the backside 57 of the integrated circuit dies 50C and 50D and make a top surface of the encapsulant 950 substantially coplanar. In some embodiments, the integrated circuit dies 50A communicates with the integrated circuit dies 50C and sends and receives signal via an electrical transmission channel 945, which includes the die connectors 66 of the integrated circuit dies 50A, the redistribution structure 122, and the die connectors 66 of the integrated circuit dies 50C. In some embodiments, the integrated circuit dies 50B communicates with the integrated circuit dies 50D and sends and receives signal via an electrical transmission channel 935, which includes the die connectors 66 of the integrated circuit dies 50B, the redistribution structure 122, and the die connectors 66 of the integrated circuit dies 50D. Thus, the electrical transmission channel 935 and 945 may be viewed as vertical electrical links.

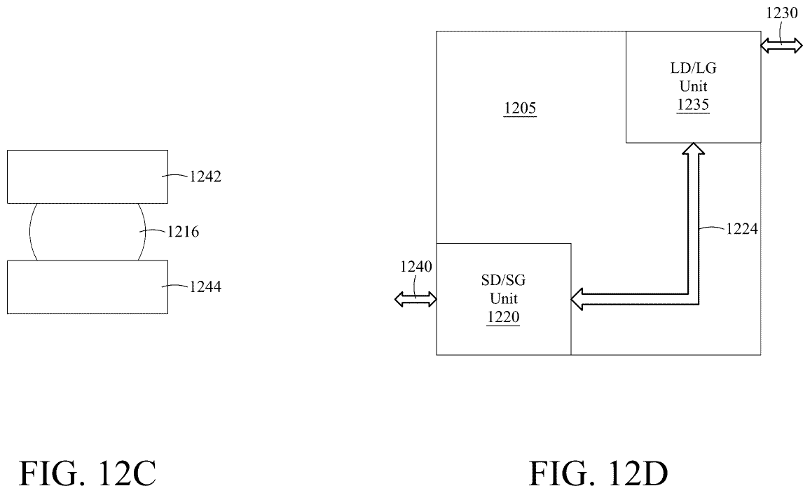

FIG. 10A is similar to the FIG. 9B with a difference that the release layer 104 is removed and the carrier substrate 102 is detached. FIG. 10B is similar to the FIG. 10A with a difference that a semiconductor layer 1010 is formed over the integrated circuit dies 50C and 50D, the optical bridge die 70, and the encapsulant 950. The optical bridge die 70 including the optical transmission channels 905, 915, and 925 and the optical structure 930 will be discussed with respect to FIGS. 11A, 11B, 11C, 11D, 11E, 11F, and 11G.

FIGS. 11A, 11B, 11C, 11D, 11E, 11F, and 11G illustrate cross-sectional views of intermediate stages for producing and optical bridge. FIG. 11A illustrates an initial structure of the optical bridge die 70 (seen in FIGS. 11F and 11G). As shown in FIG. 11A, the optical bridge die 70 is a photonic integrated circuit (PIC) and includes a substrate 101, an insulator layer 103, and a material 105 for an active layer 201 of first optical components 203 (not separately illustrated in FIG. 11A but illustrated and discussed below with respect to FIG. 11B). In some embodiments, the substrate 101, the insulator layer 103, and the material 105 for the active layer 201 of the first optical components 203 are formed on a silicon-on-insulator (SOI) substrate. The substrate 101 may be a semiconductor material such as silicon or germanium, a dielectric material such as glass, or other suitable material that allows for structural support of overlying devices.

The insulator layer 103 may be a dielectric layer that separates the substrate 101 from the overlying active layer 201 and can additionally, in some embodiments, serve as a portion of cladding material that surrounds the subsequently manufactured first optical components 203 (discussed further below). In an embodiment the insulator layer 103 may be silicon oxide, silicon nitride, germanium oxide, germanium nitride, combinations of these, or the like, formed using a method such as implantation (e.g., to form a buried oxide (BOX) layer) or else may be deposited onto the substrate 101 using a deposition method such as chemical vapor deposition, atomic layer deposition, physical vapor deposition, combinations of these, or the like. However, other suitable material and method of manufacture may be used.

The material 105 for the active layer 201, prior to patterning, may be formed as a conformal layer of the material 105. In some embodiments, the material 105 for the active layer 201 may be a translucent material that can be used as a core material for the desired first optical components 203, such as a semiconductor material such as silicon, germanium, silicon germanium, combinations of these, or the like, while in some other embodiments, the material 105 for the active layer 201 may be a dielectric material such as silicon nitride or the like, although in other embodiments the material 105 for the active layer 201 may be III-V materials, lithium niobate materials, or polymers. In some embodiments, the material 105 for the active layer 201 may be deposited using a method such as epitaxial growth, chemical vapor deposition, atomic layer deposition, physical vapor deposition, combinations of these, or the like. In some other embodiments, an insulator layer 103 is formed using an implantation method and the material 105 of the active layer 201 may initially be part of the substrate 101 prior to the implantation process to form the insulator layer 103. However, other suitable materials and methods of manufacture may be utilized to form the material 105 of the active layer 201.

As shown in FIG. 11B, the material 105 for the active layer 201 is used to form the first optical components 203 for the active layer 201. In some embodiments, the first optical components 203 of the active layer 201 includes such components as optical waveguides (e.g., ridge waveguides, rib waveguides, buried channel waveguides, diffused waveguides, etc.), couplers (e.g., grating couplers, edge couplers that are a narrowed waveguide with a width of between about 1 nm and about 200 nm, etc.), directional couplers, optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like.

The active layer 201 of first optical components 203 may be formed from the material 105 that may be patterned into the desired shapes for the active layer 201. In some embodiments, the material 105 for the active layer 201 may be patterned using, e.g., one or more photolithographic masking and etching processes. However, other suitable methods of patterning the material 105 for the active layer 201 may be utilized.

FIG. 11C illustrates that, for those components that utilize further manufacturing processes, such as Mach-Zehnder silicon-photonic switches that utilize resistive heating elements, additional processing may be performed either before or after the patterning of the material for the active layer 201. For example, implantation processes, additional deposition and patterning processes for different materials (e.g., resistive heating elements, III-V materials for converters), combinations of all of these processes, or the like, can be utilized to help further the manufacturing of the various desired first optical components 203. In a particular embodiment, and as specifically illustrated in FIG. 11C, in some embodiments, an epitaxial deposition of a semiconductor material 301 such as germanium (used, e.g., for electricity/optics signal modulation and transversion) may be performed on a patterned portion of the material 105 of the active layer 201. In such an embodiment the semiconductor material 301 may be epitaxially grown in order to help manufacture, e.g., a photodiode for an optical-to-electrical converter. All such manufacturing processes and all suitable first optical components 203 may be manufactured, and all such combinations are fully intended to be included within the scope of the embodiments.

FIG. 11D illustrates that, once the individual first optical components 203 of the active layer 201 have been formed, another insulator layer 401 may be deposited to cover the first optical components 203 and provide additional cladding material. In an embodiment the insulator layer 401 may be a dielectric layer that separates the individual components of the active layer 201 from each other and from the overlying structures and can additionally serve as another portion of cladding material that surrounds the first optical components 203. In an embodiment the insulator layer 401 may be silicon oxide, silicon nitride, germanium oxide, germanium nitride, combinations of these, or the like, formed using a deposition method such as chemical vapor deposition, atomic layer deposition, physical vapor deposition, combinations of these, or the like. Once the material of the insulator layer 401 has been deposited, the material may be planarized using, e.g., a chemical mechanical polishing process in order to either planarize a top surface of the insulator layer 401 (in embodiments in which the insulator layer 401 is intended to fully cover the first optical components 203) or else planarize the insulator layer 401 with top surfaces of the first optical components 203. However, other suitable material and methods of manufacture may be used.

FIG. 11E illustrates that, once the first optical components 203 of the active layer 201 have been manufactured and the insulator layer 401 has been formed, metallization layers 501 are formed in order to electrically connect the active layer 201 of first optical components 203 to control circuitry, to each other, and to subsequently attached devices (shown below) In an embodiment the metallization layers 501 are formed of alternating layers of dielectric and conductive material and may be formed through other suitable processes (such as deposition, damascene, dual damascene, etc.). In particular embodiments there may be multiple layers of metallization used to interconnect the various first optical components 203, but the precise number of metallization layers 501 is dependent upon the design of the optical bridge die 70. In some embodiments, the active layer 201 is consistent with the optical structure 930 of the optical bridge die 70.

Additionally, during the manufacture of the metallization layers 501, one or more second optical components 503 may be formed as part of the metallization layers 501. In some embodiments the second optical components 503 of the metallization layers 501 may include such components as couplers (e.g., edge couplers, grating couplers, etc.) for connection to outside signals, optical waveguides (e.g., ridge waveguides, rib waveguides, buried channel waveguides, diffused waveguides, etc.), optical modulators (e.g., Mach-Zehnder silicon-photonic switches, microelectromechanical switches, micro-ring resonators, etc.), amplifiers, multiplexors, de-multiplexors, optical-to-electrical converters (e.g., P-N junctions), electrical-to-optical converters, lasers, combinations of these, or the like. However, other suitable optical components may be used for the one or more second optical components 503.

In an embodiment the one or more second optical components 503 may be formed by initially depositing a material for the one or more second optical components 503. In an embodiment the material for the one or more second optical components 503 may be a dielectric material such as silicon nitride, silicon oxide, combinations of these, or the like, or a semiconductor material such as silicon, deposited using a deposition method such as chemical vapor deposition, atomic layer deposition, physical vapor deposition, combinations of these, or the like. However, other suitable material and suitable methods of deposition may be utilized.

Once the material for the one or more second optical components 503 has been deposited or otherwise formed, the material may be patterned into the desired shapes for the one or more second optical components 503. In an embodiment the material of the one or more second optical components 503 may be patterned using, e.g., one or more photolithographic masking and etching processes. However, other suitable methods of patterning the material for the one or more second optical components 503 may be utilized.

Additionally, for components such as Mach-Zehnder silicon-photonic switches that utilize resistive heating elements, additional processing may be performed either before or after the patterning of the material for the one or more second optical components 503. For example, implantation processes, additional deposition and patterning processes for different materials, combinations of all of these processes, or the like, and can be utilized to help further the manufacturing of the various desired one or more second optical components 503.

As shown in FIG. 11E, after forming the metallization layers 501, a bonding layer 505 is formed over the metallization layers 501. In an embodiment, the bonding layer 505 may be used for a dielectric-to-dielectric and metal-to-metal bond. In accordance with some embodiments, the bonding layer 505 is formed of a dielectric material 509 such as silicon oxide, silicon nitride, or the like. The dielectric material 509 may be deposited using a suitable method, such as CVD, high-density plasma chemical vapor deposition (HDPCVD), PVD, atomic layer deposition (ALD), or the like.

Once the dielectric material 509 has been formed, first openings in the dielectric material 509 are formed to expose conductive portions of the underlying layers in preparation to form bond pads 507 within the bonding layer 505. Once the first openings have been formed within the dielectric material 509, the first openings may be filled with a seed layer and a plate metal to form the bond pads 507 within the dielectric material 509. The seed layer may be blanket deposited over top surfaces of the dielectric material 509 and the exposed conductive portions of the underlying layers and sidewalls of the openings and the second openings. The seed layer may comprise a copper layer. The seed layer may be deposited using processes such as sputtering, evaporation, or plasma-enhanced chemical vapor deposition (PECVD), or the like, depending upon the desired materials. The plate metal may be deposited over the seed layer through a plating process such as electrical or electro-less plating. The plate metal may comprise copper, a copper alloy, or the like. The plate metal may be a fill material. A barrier layer (not separately illustrated) may be blanket deposited over top surfaces of the dielectric material 509 and sidewalls of the openings and the second openings before the seed layer. The barrier layer may comprise titanium, titanium nitride, tantalum, tantalum nitride, or the like.

In some embodiments, after filling of the first openings, a planarization process, such as a CMP, is performed to remove excess portions of the seed layer and the plate metal, forming the bond pads 507 within the bonding layer 505. In some embodiments a bond pad via (not separately illustrated) may also be utilized to connect the bond pads 507 with underlying conductive portions and, through the underlying conductive portions, connect the bond pads 507 with the metallization layers 501.

Additionally, bonding layer 505 may also include one or more third optical components 511 incorporated within the bonding layer 505. In such an embodiment, prior to the deposition of the dielectric material 509, the one or more third optical components 511 may be manufactured using similar methods and similar materials as the one or more second optical components 503 (described above), such as by being waveguides and other structures formed at least in part through a deposition and patterning process. However, other suitable structures, materials and methods of manufacture may be utilized.

FIG. 11F shows an optical bridge 70A consistent with the optical bridge die 70 that is used in FIGS. 9A, 9B, 10A, and 10B. The optical bridge 70A is similar to the optical bridge die 70 of FIG. 11E with the difference that the substrate 101 and the insulator layer 103 are removed (etched). Then, the optical bridge die 70 is flipped and a semiconductor layer 1102 formed on active layer 201. Also, one of the second optical components, e.g., an optical component 510 (e.g., a waveguide), is essentially extended between the first end and the second end of the optical bridge 70A to perform as a waveguide for the optical transmission channels 905. Additionally, the bond pads 507 may connect to the bond pads 138 of the redistribution structure 122 when the optical bridge 70A is mounted on the redistribution structure 122 to provide power, via the metallization layers 501 to the first optical components 203 of active layer 201. The first optical components 203 and the second optical components 503 may direct the optical signals between the first and second ends of the optical bridge 70A.

FIG. 11G shows an optical bridge 70B consistent with the optical bridge die 70 that is used in FIGS. 9A, 9B, 10A, and 10B. The optical bridge 70B is similar to the optical bridge die 70 of FIG. 11E with the difference that the bond pads 507 are not directly connected to the metallization layers 501 but the semiconductor layer 1102 is attached to the metallization layer 501 opposite to a side the active layer 201 is attached. Another dielectric material 1110, consistent with the dielectric material 509, is formed over the active layer 201 and includes one of the second optical components, e.g., the optical component 510, which may be a waveguide or an optical cable that is essentially extended between the first end and the second end of the optical bridge 70B to perform as a waveguide for the optical transmission channels 905. Additionally, the bond pads 507 are formed on the dielectric material 1110. One or more TSVs 1115 extend from bond pads 507 to the metallization layers 501. When the optical bridge 70B is mounted on the redistribution structure 122, the bond pads 138 of the redistribution structure 122 may provide power and ground connections, via the bond pads 507, the TSVs 1115, and the metallization layers 501 to the first optical components 203 of active layer 201. The first optical components 203 and the second optical components 503 may direct the optical signals between the first and second ends of the optical bridge 70B. In some embodiments, the optical component 510 is a silicon waveguide.

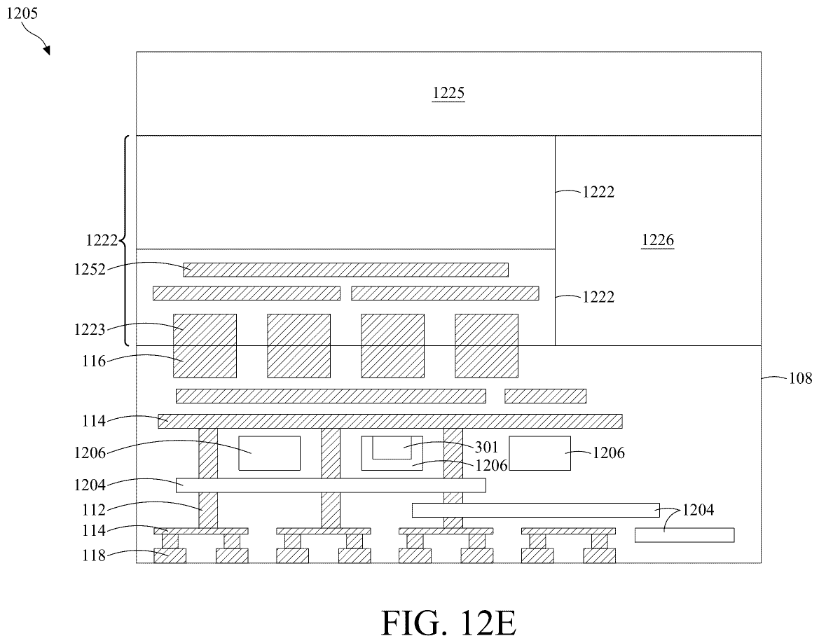

FIGS. 12A, 12B, 12C, 12D, and 12E illustrate a cross-sectional view of a semiconductor package on a substrate, a solder bump structure, a system-level diagram of an optical interface engine, and a cross-sectional view of and optical interface engine, in accordance with some embodiments. FIG. 12A is similar to FIG. 10A but additionally shows that the integrated circuit of FIG. 10A is mounted, e.g., connected and electrically coupled, to a package substrate 1210, which is the substrate of the package. In some embodiments, the integrated circuit dies 50A and 50B are ASIC dies and the integrated circuit dies 50C and 50D are memory dies that include data lines 1234 and memory segments 1232. Each memory die may communicate and may be dedicated to the ASIC die that is mounted below the memory die and signal communication and data transfer happens in a short distance through the redistribution structure 122 via electrical transmission channel 935 and 945 and, thus, signal communication and data transfer may become fast and reliable. Also, because signal and data communication between the ASIC dies are optical and through the optical bridge die 70, signal and data communication between the ASIC dies are also reliable and fast. Also, an underfill material 1212 is between the package substrate 1210 and the redistribution structure 122. The integrated circuit dies 50A and 50B are connected such that the front-side interconnect structure 107 of the layer 47 is in contact with the redistribution structure 122 and the TSVs 55 are connected via solder balls 1216 to the package substrate 1210. Also, solder balls 1214 are attached to the side of the package substrate 1210 that is opposite the side the solder balls 1216 are connected. The solder balls 1214 may be used for mounting the package and providing electrical connection to the package substrate 1210. As shown, the combination of the ASIC dies and memory dies, the optical bridge die 70, and the redistribution structure 122 provides an integrated circuit 1280.

FIG. 12B is similar to the FIG. 12A that also includes an optical interface (OI) engine 1205 that is also mounted and is in electrical contact via solder balls 1236 with the package substrate 1210. The ASIC dies of the integrated circuit 1280 and the OI engine 1205 may communicate through the package substrate 1210 and OI engine 1205 may transmit data, e.g., optical signals 1230, through an optical fiber channel attached to the OI engine 1205. FIG. 12C shows how solder balls 1216 or other solder balls or solder bumps are connected. As shown, each solder ball 1216 is attached between two bond pads. For example, in FIG. 12B, the bond pad 1242 is attached or might be part of the ASIC dies and the bond pad 1244 is attached or might be part of the package substrate 1210.

FIG. 12D shows the system-level diagram of the OI engine 1205. The OI engine 1205 may receive electrical signals 1240 that may include power signals through the package substrate 1210, that may originate from the ASIC dies (integrated circuit dies 50A or 50B), via the solder balls 1236. In some embodiments, the electrical signals 1240 are received by an electrical signal detector/signal generator unit 1220. The electrical signal detector/signal generator unit 1220 may detect and analyze the electrical signals and generate detected electrical signals 1224. In some embodiments, the electrical signal detector/signal generator unit 1220 cleans, e.g., removes the noise of, the electrical signals 1240. After the detection, the electrical signal detector/signal generator unit 1220 may perform a data check, e.g., a parity check on the received electrical signals 1240. The detected electrical signals 1224 are sent to a light detector/light generator unit 1235 to be converted to optical signals 1230. The optical signals 1230 are sent via an optical cable to the other systems. Thus, the light detector/light generator unit 1235 may include one or more light sources, e.g., light emitting diodes (LED) or laser diodes, that transform the detected electrical signals 1224 to the optical signals 1230.

Conversely, the light detector/light generator unit 1235 may receive the optical signals 1230 from the other systems, detect the optical signals 1230 by one or more light detectors of the light detector/light generator unit 1235, and generate the electrical signals 1224 that correspond to the detected optical signals 1230. The electrical signals 1224 may be sent to the electrical signal detector/signal generator unit 1220 to be sent as the electrical signals 1240, via the conductive connectors, e.g., the solder balls 1236, of the OI engine 1205 and through the package substrate 1210, to the ASIC dies. Thus, the OI engine 1205 is consistent with the electrical/optical signal converters 910 and 920.

FIG. 12E shows a cross-sectional view of the OI engine 1205 and shows waveguides 1204, photonic components 1206, and electrical routing 114 that are formed within a plurality of dielectric layers 108, in accordance with some embodiments. In some embodiments, a substrate (not individually indicated) may first be provided. The substrate may be, for example, a BOX substrate comprising a buried oxide layer and a semiconductor layer over the buried oxide layer. In other embodiments, the substrate may be, for example, glass, ceramic, dielectric, a semiconductor, the like, or a combination thereof. In some embodiments, the substrate may be a semiconductor substrate, such as a bulk semiconductor or the like, which may be doped (e.g., with a p-type or an n-type dopant) or undoped. The substrate may be a wafer, such as a silicon wafer (e.g., a 12-inch silicon wafer). Other substrates, such as a multi-layered or gradient substrate may also be used. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. The oxide layer 102B may be, for example, a silicon oxide or the like.

In some embodiments, one or more semiconductor layers of the substrate are patterned to form a plurality of photonic components 1206, which may also be referred to as silicon devices that are similar to optical components 203 and may include the semiconductor material 301. Some examples of the photonic components 1206 include waveguides, photonic devices, optical modulators, mode converters, photodetectors, grating couplers, or the like. The semiconductor layer may be patterned using suitable photolithography and etching techniques, which may involve etching processes using photoresists to define patterns. In accordance with some embodiments, the photonic components 1206 are physically and/or optically coupled to a waveguide 1204 in order to optically interact with that waveguide 1204 through optical signals. The waveguide 1204 may be formed with the photonic components 1206 (e.g. formed from the same semiconductor layer) or may be formed in separate manufacturing steps. For example, a photodetector may be optically coupled to a waveguide 1204 to detect optical signals within the waveguide 1204 and generate electrical signals corresponding to the optical signals. A modulator may also receive electrical signals and modulate optical power within a waveguide 1204 to generate corresponding optical signals. In this manner, a photonic components 1206 may input optical signals from, or output optical signal to, a waveguide 1204. In accordance with other embodiments, the photonic components 1206 may include other active or passive components, such as laser diodes, optical signal splitters, grating couplers, edge couplers, or other types of photonic components or devices.

In some embodiments, multiple layers of waveguides 1204 may be formed in the dielectric layers 108. The waveguides 1204 may be optically coupled to other waveguides 1204 in the same layer and/or in a neighboring layer. For example, the waveguides 1204 may be optically coupled using edge couplers, grating couplers, mode converters, or other types of optically coupling structures. The waveguides 1204 may be formed of similar materials or different materials. For example, in some embodiments, the waveguides 1204 may be formed of silicon. Silicon waveguides may be formed, for example, by depositing a layer of silicon and then patterning the layer of silicon using suitable photolithography and etching techniques. A respective dielectric layer may be deposited over each layer of silicon waveguides. In some embodiments, the waveguides 1204 may be formed of silicon nitride. Nitride waveguides may be formed, for example, by depositing a layer of silicon nitride and then patterning the layer of silicon nitride using suitable photolithography and etching techniques. The deposition process may include CVD, PECVD, LPCVD, PVD, or the like. In other embodiments, the waveguides 1204 may be formed of silicon oxynitride, polymer, or another material. Other materials are possible. A photonic package 100 may comprise one type of waveguide or multiple types of waveguides. In some cases, nitride waveguides may have advantages over silicon waveguides, described in greater detail below.

The dielectric layers 108 may comprise one or more suitable materials such as silicon oxide, polymer, spin-on glass, flowable oxide, or the like. The dielectric layers 108 may be formed using suitable techniques, such as CVD, flowable CVD, PVD, spin-on coating, lamination, or the like. In some embodiments, one or more of the dielectric layers 108 may be planarized using a chemical mechanical polish (CMP) process or the like.

Still referring to FIG. 12E, electrical routing 114, through vias 112, bond pads 116, and/or bond pads 118 may be formed in or on various dielectric layers 108, in accordance with some embodiments. The electrical routing 114 may comprise conductive lines, conductive vias, conductive contacts, redistribution layers, metallization layers, or the like. The electrical routing 114 may electrically contact the photonic components 1206, and may provide interconnections therebetween in some embodiments. In some embodiments, through vias 112 may be formed extending through one or more dielectric layers 108 to electrically connect different regions of electrical routing 114. Bond pads 116/118 may be formed on upper or lower surfaces of the dielectric layers 108 to allow for electrical connection to other structures, dies, substrates, components, or the like. Thus, in some embodiments, the dielectric layers 108 provide a PIC die.

The electrical routing 114, through vias 112, bond pads 116, and/or bond pads 118 may be formed in one or more suitable processes. For example, the process may comprise a damascene process, a dual damascene process, or another suitable process. As another example, the formation of the through vias may include etching-through one or more dielectric layers 108 to form openings and then filling the openings with conductive materials such as titanium nitride, tantalum nitride, titanium, copper, tungsten, cobalt, ruthenium, the like, or a combination thereof. There may or may not be a dielectric liner formed encircling the various conductive materials used in any of these conductive features. In some embodiments, the bond pads 116 and/or the bond pads 118 may be conductive pads, conductive pillars, or the like. Other conductive features, arrangements, or configurations are possible. In some embodiments, the bond pads 118 are connected to the solder balls 1236 and via the solder balls 1236 to the package substrate 1210.

In FIG. 12E, one or more electronic dies 1222 are bonded to the bond pads 116, in accordance with some embodiments. The electronic dies 1222 may be, for example, semiconductor devices, dies, or chips that communicate with the photonic components 1206 using electrical signals. The OI engine 1205 may include two or more electronic dies 1222 in other embodiments. In some cases, multiple electronic dies 1222 may be incorporated into a single photonic package 100 in order to reduce processing cost. The electronic die 1222 may include die connectors 1223, which may be, for example, conductive pads, conductive pillars, or the like.

The electronic die 1222 may include integrated circuits for interfacing with the photonic components 1206, such as circuits for controlling the operation of the photonic components 1206. For example, the electronic die 1222 may include controllers, drivers, trans-impedance amplifiers, the like, or combinations thereof. The electronic die 1222 may also include a CPU, in some embodiments. In some embodiments, the electronic die 1222 includes circuits for processing electrical signals received from photonic components 1206, such as for processing electrical signals received from a photonic component 1206 including a photodetector. The electronic die 1222 may control high-frequency signaling of the photonic components 1206 according to electrical signals (digital or analog) received from another device or die, in some embodiments. In some embodiments, the electronic die 1222 may be an electronic integrated circuit (EIC) or the like that provides Serializer/Deserializer (SerDes) functionality. In this manner, the electronic die 1222 may act as part of an I/O interface between optical signals and electrical signals within the OI engine 1205.

In some embodiments, an electronic die 1222 is bonded to the redistribution structure 122 by dielectric-to-dielectric bonding and/or metal-to-metal bonding (e.g., direct bonding, fusion bonding, oxide-to-oxide bonding, hybrid bonding, or the like). In such embodiments, covalent bonds may be formed between bonding layers, such as the topmost dielectric layer 108 and surface dielectric layers (not individually shown) of the electronic die 1222. During the bonding, metal-to-metal bonding may also occur between the die connectors 1223 of the electronic die 1222 and the bond pads 116. The electronic dies 1222 may include electrical routing 1252 to provide electrical connection to electronic devices of the electronic dies 1222. In some embodiments, one or more electronic dies 1222 are ASIC dies that are mounted over the PIC die of the dielectric layers 108.

In FIG. 12E, a dielectric material 1226 may be formed over the electronic die 1222 and the dielectric layers 108, in accordance with some embodiments. The dielectric material 1226 may be formed of silicon oxide, silicon nitride, a polymer, the like, or a combination thereof. The dielectric material 1226 may be formed by CVD, PVD, ALD, a spin-on-dielectric process, the like, or a combination thereof. In some embodiments, the dielectric material 1226 may be formed by HDP-CVD, FCVD, the like, or a combination thereof. The dielectric material 1226 may be a gap-fill material in some embodiments, which may include one or more of the example materials above. Other dielectric materials formed by any acceptable process may be used. The dielectric material 1226 may be planarized using a planarization process such as a CMP process, a grinding process, or the like. In some embodiments, as shown, the planarization process may expose the electronic die 1222 such that a surface of the electronic die 1222 and a surface of the dielectric material 1226 are coplanar.

Further in FIG. 12E, a support layer 1225 is attached to the structure, in accordance with some embodiments. The support layer 1225 is a rigid structure that is attached to the structure in order to provide structural or mechanical stability. The use of a support layer 1225 may reduce warping or bending, which can improve the performance of the optical structures such as the waveguides 1204 or photonic components 1206. The support layer 1225 may include one or more materials such as silicon (e.g., a silicon wafer, bulk silicon, or the like), a silicon oxide, a metal, an organic core material, the like, or another type of material. The support layer 1225 may be attached to the structure (e.g., to the dielectric material 1226 and/or the electronic dies 1222) using an adhesive layer, direct bonding, or another suitable technique. The support layer 1225 may also have lateral dimensions (e.g., length, width, and/or area) that are greater than, about the same as, or smaller than those of the structure.

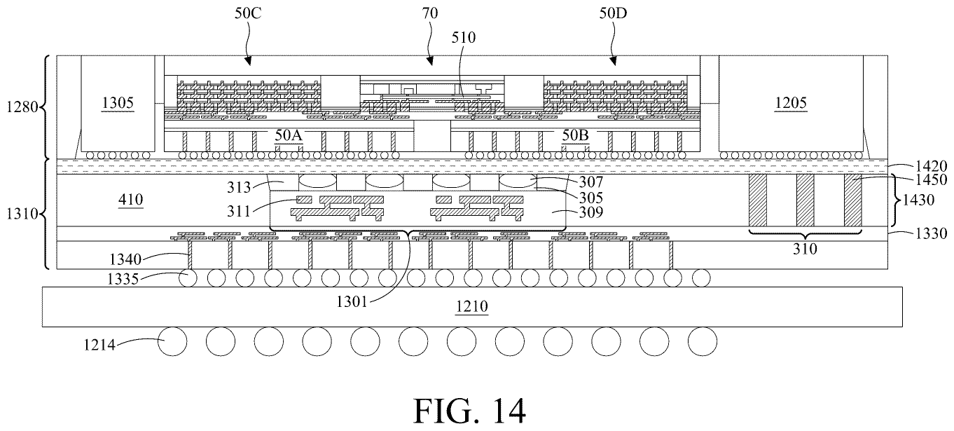

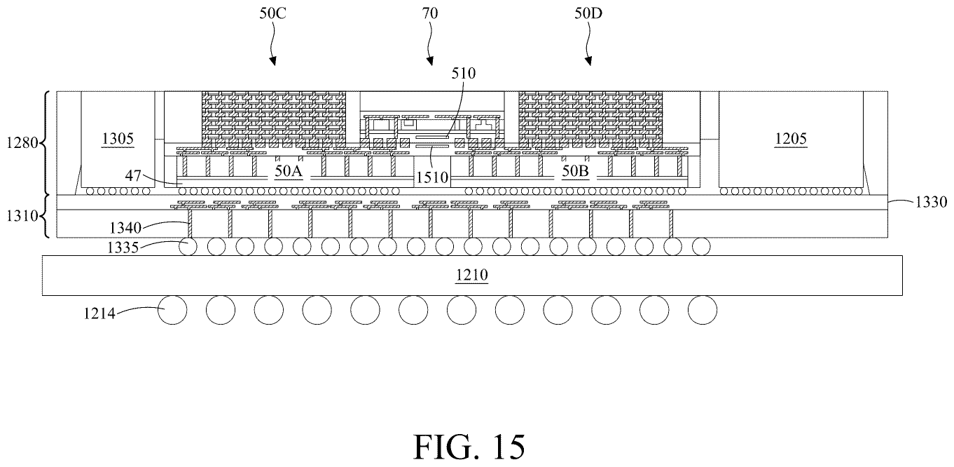

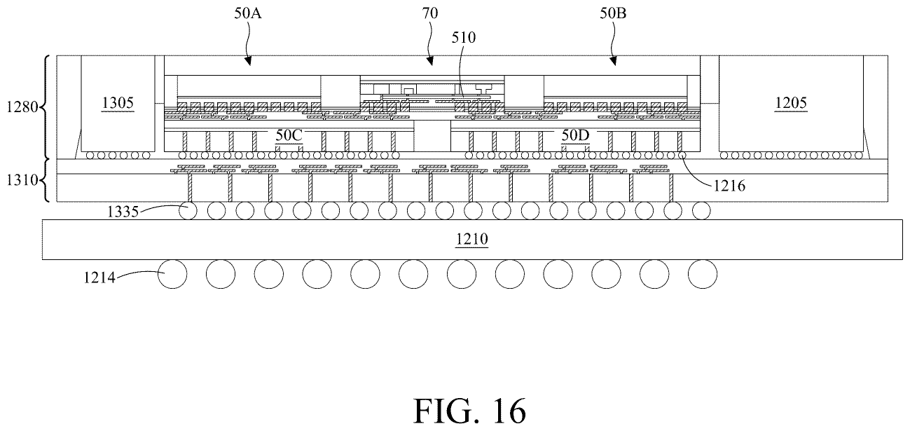

FIGS. 13, 14, 15, and 16 illustrate a cross-sectional view of a semiconductor package, an optical interface engine, and a device mounted on an interposer and the interposer is mounted on a substrate, in accordance with some embodiments. FIG. 13 shows the integrated circuit 1280 that is mounted on an interposer 1310 and the interposer 1310 is mounted via solder balls 1335 on the package substrate 1210. The interposer 1310 includes another redistribution structure 1330 mounted on a substrate 1345 that includes a plurality of TSVs 1340. FIG. 13 also shows an integrated device 1305, e.g., a memory device, that is also mounted on the interposer 1310 and is connected to the integrated circuit 1280. As shown, FIG. 14 is similar to FIG. 13 with a difference that the interposer 1310 further includes an interconnect structure 1430 that includes one or more interconnect devices 1301 (e.g., local silicon interconnects (LSI), or the like) and one or more pluralities 310 of the TMVs 1450 that are disposed over the redistribution structure 1330 and are covered by the encapsulant 410 (e.g., molding). FIG. 14 also includes yet another redistribution structure 1420 over the interconnect structure 1430. The interconnect devices 1301 includes conductive connectors 305, a solder material 307, a substrate 309, underfill 313, and electrical routing 311 (e.g., metallization patterns, metal lines and via). FIG. 15 is similar to FIG. 13 with a difference that the first integrated circuit die 50A and the second integrated circuit die 50B are flipped and the die connectors 66 are connected to redistribution structure 1330 and the TSVs 55 are connected to the redistribution structure 122. Also, in FIG. 15, another waveguide 1510 is extended inside the redistribution structure 122. In some embodiments, the waveguide 1510 are connected and, thus, the different optical bridges are optically connected such that any ASIC die may optically communicate with another ASIC die. FIG. 16 is similar to FIG. 15 with a difference that the location of the integrated circuit die 50A and the integrated circuit die 50B are changed with the location of the integrated circuit die 50C and the integrated circuit die 50D respectively. The integrated circuit die 50A and the integrated circuit die 50B that optically communicate are at the same side of the redistribution structure 122 as the optical bridge die 70. In some embodiments, the waveguide 1510 inside the redistribution structure 122 is a silicon nitride waveguide. In some embodiments, the bond pads 118 of the OI engine 1205 are connected to the solder balls 1236 and via the solder balls 1236 to the redistribution structure 1330.

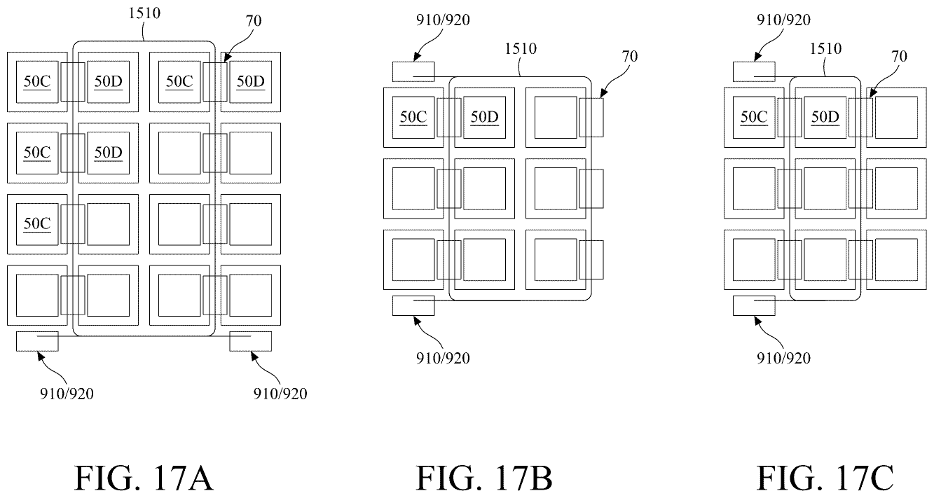

FIGS. 17A, 17B, and 17C illustrate a plan view of the semiconductor package. FIGS. 17A, 17B, and 17C show the integrated circuit die 50C and the integrated circuit die 50D with the integrated circuit die 50A and the integrated circuit die 50B that are substantially located below that not shown. FIGS. 17A, 17B, and 17C are consistent with FIGS. 12A, 12B, 13, 14, and 15. The figures also show the optical bridge dies 70 that provide optical communication between the integrated circuit die 50A and the integrated circuit die 50B. The FIGS. 17A, 17B, and 17C also show that the optical bridge dies 70 are optically connected via a waveguide, e.g., the waveguide 1510. As described before, the signal converter 910 or 920 may generate an optical signal, e.g., a laser diode of the signal converter 910 or 920 may produce the optical signals from the electrical signals. Then, any signal converter 910 or 920 in the loop may receive the optical signal and my convert the optical signal to electric signal. Therefore, each one of the integrated circuit dies may optically be connected to other integrated circuit dies.

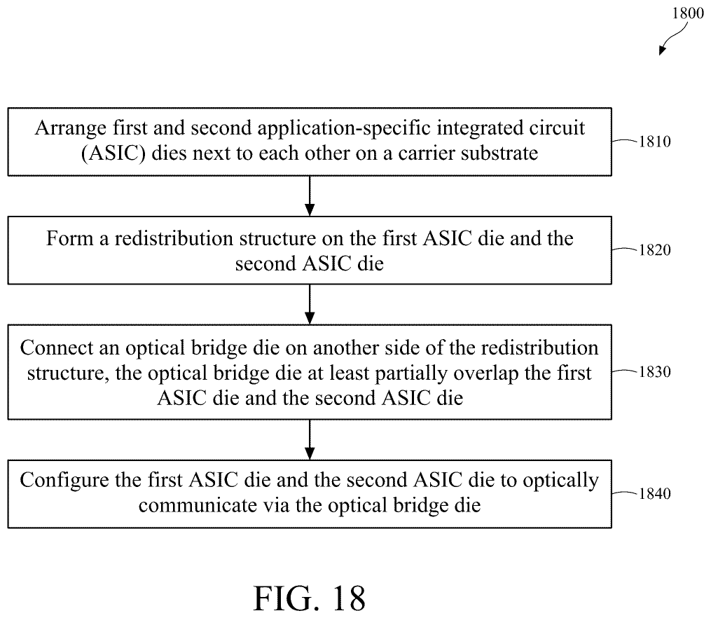

FIG. 18 illustrates a flow diagram of a process 1800 for generating a packaged semiconductor device, according to some embodiments of the disclosure. The steps of the process are shown in FIGS. 2, 3, 4, 6, 7, 9A, 10A, 12A, 13, and 14. At step 1810, a first ASIC die and a second ASIC die are arranged next to each other on a carrier substrate. As shown in FIG. 3, the first integrated circuit die 50A and the second integrated circuit die 50B are arranged on the carrier substrate 102. The integrated circuit dies 50A and 50B are ASIC dies and are next to each other such that as shown in FIG. 4. In some embodiments, a distance between the ASIC dies is less than the maximum of the extent of the ASIC dies, or may be less than ten to twenty times the maximum of the extent of the ASIC dies.

At step 1820, a redistribution structure is formed that is connected and is electrically coupled to a front side of the first and on the second integrated circuit dies. As shown in FIGS. 6 and 7, the redistribution structure 122 (a first side of the redistribution structure 122) is formed on the front side 59 of the first and second integrated circuit dies 50A and 50B (the ASIC dies). As shown, in some embodiments, the redistribution structure 122 is connected and is electrically coupled to the first and second ASIC dies via the die connectors 66. In some embodiments the ASIC dies are flipped and the backside 57, e.g., the TSVs 55, are connected to the redistribution structure 122.

At step 1830, an optical bridge die is connected and is electrically coupled to the redistribution structure, opposite to a side connected to the first and the second ASIC dies, the optical bridge is at least partially overlapping the first and/or the second ASIC die, e.g., the optical bridge die 70 is connected at one side of the redistribution structure 122 and the first and the second integrated circuit dies 50A and 50B (ASIC dies) are connected at another opposite side of the redistribution structure 122 and the optical bridge die 70 is at least partially overlapping the first and the second integrated circuit dies 50A and 50B as described above. As shown in FIG. 9A, the optical bridge die 70 is connected and is electrically coupled to the redistribution structure 122 via bond pads 138.

At step 1840, configure the first ASIC die and the second ASIC die to optically communicate via the optical bridge die. As shown in FIG. 9A and described above the first and the second ASIC dies optically and bi-directionally communicate through the optical bridge die 70. Each one of the ASIC dies include the electrical/optical signal converters 910 and 920 that are located in a section of the ASIC dies under the optical bridge die 70 that convert the optical signals to electric signals and vice versa and sends and receives the optical signals to and from the optical bridge die 70, which is a photonic integrated circuit.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

As such, the packaged semiconductor system of FIG. 12B, 13, 14, 15, or 16 may be used in advanced networking and server applications (e.g., AI (Artificial Intelligence)) which operate with high data rates, high bandwidth demands and low latency. Furthermore, the of the packaged semiconductor system of the FIG. 12B, 13, 14, 15, or 16 may be provided a high degree of chip package integration in a small form factor with high component and board level reliability.

According to an embodiment, a semiconductor package includes a redistribution structure, first and second integrated circuit dies connected to a first side of the redistribution structure, third and fourth integrated circuit dies connected on a second side, opposite to the first side, of the redistribution structure, and an optical bridge die connected between the third and fourth integrated circuit dies to the second side of the redistribution structure. The first and second integrated circuit dies optically communicate through the optical bridge die.

In an embodiment, the first and second integrated circuit dies are mounted over the third and fourth integrated circuit dies such that the first integrated circuit die has partial overlap with the third integrated circuit die and the second integrated circuit die has partial overlap with the fourth integrated circuit die. The first integrated circuit die and the third integrated circuit die electrically communicate with each other through the redistribution structure and the second integrated circuit die and the fourth integrated circuit die electrically communicate with each other through the redistribution structure. In an embodiment, the first integrated circuit die includes a first signal converter that generates first optical signals based on first electrical signals of the first integrated circuit die and transmits the first optical signals to the optical bridge die. Also the second integrated circuit die includes a second signal converter that generates second optical signals based on second electrical signals of the second integrated circuit die and transmits the second optical signals to the optical bridge die. In an embodiment, the optical bridge die includes first optical components such that the optical bridge die receives and transmits optical signals through a length of the optical bridge die from one end to an opposite end of the optical bridge die. In an embodiment, the first, the second, the third, and the fourth integrated circuit dies include die connectors at a front side of the respective integrated circuit die, and the first side of the redistribution structure is electrically coupled to the first and second integrated circuit dies via the die connectors. Also, the second side of the redistribution structure includes bond pads, and the third and the fourth integrated circuit dies are electrically coupled to the redistribution structure via the bond pads and the die connectors. In an embodiment, the semiconductor package further includes a package substrate such that the first and second integrated circuit dies are connected via solder bumps to the package substrate. The package substrate includes first connection pads such that the solder bumps are connected between the first connection pads of the package substrate and second connection pads that are coupled to through-substrate-vias of the first and second integrated circuit dies. In an embodiment, the semiconductor package further includes a first encapsulant surrounding the first and second integrated circuit dies, a second encapsulant surrounding the third and fourth integrated circuit dies, and an underfill material between the package substrate and the redistribution structure.

According to an embodiment, a semiconductor package includes a redistribution structure, a first integrated circuit die and a second integrated circuit die connected to a first side of the redistribution structure. The semiconductor package also include an optical bridge die that is connected to a second side, opposite to the first side, of the redistribution structure. The optical bridge die partially overlaps the first integrated circuit die and the second integrated circuit die. The first integrated circuit die and the second integrated circuit die optically communicate through the optical bridge die.

In an embodiment, the second integrated circuit die includes a first signal converter that converts first electrical signals of the second integrated circuit die to first optical signals and transmits the first optical signals to the optical bridge die. The first integrated circuit die includes a second signal converter that receives the first optical signals from the optical bridge die and re-produces the first electrical signals based on the first optical signals. In an embodiment, the optical bridge die includes an active layer, a metallization layer, and two or more bond pads that are electrically coupled to the metallization layer. The optical bridge die is electrically coupled to the redistribution structure via the bond pads and the active layer of the optical bridge die receives electrical power from the redistribution structure via the bond pad and the metallization layer. In an embodiment, the optical bridge die transmits optical signals through a length of the optical bridge die from one end to an opposite end of the optical bridge die. Also, the optical bridge die is bi-directional. In an embodiment, each one of the first integrated circuit die and the second integrated circuit die includes die connectors and the semiconductor package further includes an encapsulant surrounding the first integrated circuit die and the second integrated circuit die. In an embodiment, the semiconductor package further includes a package substrate and the first and second integrated circuit dies are connected via solder bumps to the package substrate. The package substrate includes first connection pads and the solder bumps are connected between the first connection pads of the package substrate and the die connectors of the first and second integrated circuit dies. In an embodiment, the first and second integrated circuit dies are coupled to the redistribution structure using through-substrate-vias of the first and second integrated circuit dies.

According to an embodiment, a method include arranging first and second application-specific integrated circuit (ASIC) dies next to each other on a carrier substrate, forming a redistribution structure on the first ASIC die and the second ASIC die such that a first side of the redistribution structure overlapping the first ASIC die and the second ASIC die. The method further includes connecting an optical bridge die on a second side of the redistribution structure. The optical bridge die at least partially overlap the first ASIC die and the second ASIC die and the first ASIC die and the second ASIC die optically communicate via the optical bridge die.

In an embodiment, the method further includes disposing an encapsulant on the carrier substrate such that the encapsulant is disposed around and between the first ASIC die and the second ASIC die. In an embodiment, the method further includes removing the carrier substrate from a backside of the first and second ASIC dies. In an embodiment, the method further includes mounting the first ASIC die and the second ASIC die on a package substrate, and mounting an optical engine interface on the package substrate next to the first ASIC die and the second ASIC die. In an embodiment, the method further includes mounting the first ASIC die and the second ASIC die on an interposer, mounting an optical interface engine on the interposer, and mounting an integrated device on the interposer. In an embodiment, the integrated device is a memory device, and the method further includes mounting the interposer on a package substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a redistribution structure;
a first integrated circuit die and a second integrated circuit die bonded to a first side of the redistribution structure; and
an optical bridge die bonded to a second side of the redistribution structure, wherein the first integrated circuit die is communicatively coupled to the second integrated circuit die through an optical communication path, and wherein the optical communication path includes an optical component within the optical bridge die.

2. The semiconductor package of claim 1,
wherein the first integrated circuit die comprises a first signal converter configured to generate first optical signals based on first electrical signals of the first integrated circuit die and to transmit the first optical signals to the optical bridge die, and
wherein the second integrated circuit die comprises a second signal converter configured to generate second optical signals based on second electrical signals of the second integrated circuit die and to transmit the second optical signals to the optical bridge die.

3. The semiconductor package of claim 1 further comprising:
a third integrated circuit die bonded to the second side of the redistribution structure, wherein the redistribution structure electrically connects the first integrated circuit die to the third integrated circuit die.

4. The semiconductor package of claim 3, wherein the third integrated circuit die at least partially overlaps the first integrated circuit die.

5. The semiconductor package of claim 1 further comprising:
a first encapsulant surrounding the first integrated circuit die and the second integrated circuit die; and
a second encapsulant surrounding the optical bridge die.

6. The semiconductor package of claim 1, wherein the first integrated circuit die and the second integrated circuit die are bonded to the redistribution structure by dielectric-to-dielectric and metal-to-metal bonding.

7. The semiconductor package of claim 1, wherein the optical bridge die is bonded to the redistribution structure by dielectric-to-dielectric and metal-to-metal bonding.

8. The semiconductor package of claim 1 further comprising external connectors on a side of the first integrated circuit die that is opposite to the redistribution structure, wherein the external connectors are electrically connected to the redistribution structure by the first integrated circuit die.

9. The semiconductor package of claim 8 further comprising:
a package substrate bonded to the external connectors; and
an underfill surrounding the external connectors.

10. A semiconductor package, comprising:
a redistribution structure;
a first integrated circuit die and a second integrated circuit die directly bonded to a first side of the redistribution structure;
a first encapsulant surrounding the first integrated circuit die;
an optical bridge die directly bonded to a second side of the redistribution structure, wherein the first integrated circuit die and the second integrated circuit die are configured to optically communicate through the optical bridge die; and
a third integrated circuit die directly bonded to the second side of the redistribution structure, wherein the redistribution structure electrically connects the third integrated circuit die to the first integrated circuit die.

11. The semiconductor package of claim 10, wherein the second integrated circuit die comprises a first signal converter configured to convert first electrical signals of the second integrated circuit die to first optical signals and to transmit the first optical signals to the optical bridge die, and wherein the first integrated circuit die comprises a second signal converter, wherein the second signal converter is configured to receive the first optical signals from the optical bridge die and to re-produce the first electrical signals based on the first optical signals.

12. The semiconductor package of claim 10 further comprising:
a fourth integrated circuit die directly bonded to the second side of the redistribution structure, wherein the redistribution structure electrically connects the fourth integrated circuit die to the second integrated circuit die.

13. The semiconductor package of claim 12, wherein the optical bridge die is disposed between the third integrated circuit die and the fourth integrated circuit die.

14. The semiconductor package of claim 10, wherein the first integrated circuit die is partially overlapped by the third integrated circuit die and the optical bridge die.

15. The semiconductor package of claim 10, further comprising:
a package substrate, wherein the first integrated circuit die and the second integrated circuit die are connected via solder bumps to the package substrate, and wherein the solder bumps are electrically connected to first through substrate vias in the first integrated circuit die and second through substrate vias in the second integrated circuit die.

16. The semiconductor package of claim 10, wherein a portion of the first encapsulant extends continuously from a sidewall of the first integrated circuit die to a sidewall of the second integrated circuit die, and wherein the optical bridge die fully overlaps the portion of the encapsulant in a cross-sectional view.

17. A semiconductor package comprising:
a first package component comprising:
a redistribution structure;
a first integrated circuit die and a second integrated circuit die bonded to a first side of the redistribution structure; and
an optical bridge die bonded to a second side of the redistribution structure that is opposite to the first side of the redistribution structure, wherein the first integrated circuit die and the second integrated circuit die are optically connected by an optical component in the optical bridge die;
a package substrate bonded to the first package component by solder connectors; and
an underfill between the package substrate and the first package component, wherein the underfill surrounds the solder connectors, and wherein the underfill extends along sidewalls of the first package component.

18. The semiconductor package of claim 17, wherein the underfill extends along sidewalls of the redistribution structure.

19. The semiconductor package of claim 17 further comprising:
a third integrated circuit die and a fourth integrated circuit die bonded to the second side of the redistribution structure, wherein the third integrated circuit die is electrically connected to the first integrated circuit die, and wherein the fourth integrated circuit die is electrically connected to the second integrated circuit die.

20. The semiconductor package of claim 17, wherein the first package component further comprises a semiconductor layer attached to a surface of the optical bridge die that is opposite to the redistribution structure.
